(19) United States
(12) Patent Application Publication
(10) Pub. No.: US 2023/0338914 A1
(43) Pub. Date: Oct. 26, 2023

(54) SUBSTRATE PROCESSING APPARATUS INCLUDING EXHAUST DUCT WITH A BEVEL MASK WITH A PLANAR INNER EDGE

(71) Applicant: ASM IP Holding B.V., Almere (NL)

(72) Inventor: Ping Ren, Tokyo (JP)

(21) Appl. No.: 18/137,800

(22) Filed: Apr. 21, 2023

Related U.S. Application Data
(60) Provisional application No. 63/334,747, filed on Apr. 26, 2022.

(51) Int. Cl. B01J 19/00; B01J 19/24

(52) U.S. Cl. CPC B01J 19/0053; B01J 19/247; B01J 2219/029

(57) ABSTRACT

A substrate processing apparatus is disclosed. Exemplary substrate processing apparatus includes a reaction chamber provided with a chamber wall; a susceptor disposed within the reaction chamber to support a substrate; a gas supply unit to supply a gas to the substrate; and an exhaust duct disposed within the reaction chamber, comprising: an inner ring comprising a first inner end and a second inner end; wherein the first inner end is configured to contact a bottom of the chamber wall; and an outer ring provided with a plurality of holes, the outer ring comprising a first outer end and a second outer end; wherein the first outer end is configured to contact a side of the chamber wall and the second outer end is configured to be engaged with the second inner end.

### CROSS-REFERENCE TO RELATED APPLICATIONS

This application claims priority to U.S. Provisional Pat. Application Serial No. 63/334,747 filed Apr. 26, 2022 titled SUBSTRATE PROCESSING APPARATUS INCLUDING EXHAUST DUCT, the disclosure of which is hereby incorporated by reference in its entirety.

### FIELD OF INVENTION

The present disclosure relates generally to a substrate processing apparatus. More particularly, exemplary embodiments of the present disclosure relate to a substrate processing apparatus including an exhaust duct.

### BACKGROUND OF THE DISCLOSURE

Gases in a substrate processing chamber needs to be exhausted, such as chemical vapor deposition (CVD) and atomic layer deposition (ALD) operations. An exhaust duct is disposed in the substrate processing chamber. The exhaust duct is fluidly coupled to a vacuum pump through a foreline.

However, due to a misalignment of the exhaust duct, evacuation of the gases around a substrate is sometimes not symmetrical, which can lead to non-uniform processing. Thus, a solution is desired that allows for symmetrical evacuation of gases, which may lead to more uniform processing of substrates.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a reaction chamber provided with a chamber wall; a susceptor disposed within the reaction chamber to support a substrate; a gas supply unit to supply a gas to the substrate; and an exhaust duct disposed within the reaction chamber, comprising: an inner ring comprising a first inner end and a second inner end; wherein the first inner end may be configured to contact a bottom of the chamber wall; and an outer ring provided with a plurality of holes, the outer ring comprising a first outer end and a second outer end; wherein the first outer end may be configured to contact a side of the chamber wall and the second outer end may be configured to be engaged with the second inner end.

In various embodiments, the inner ring may have a L-shaped cross section.

In various embodiments, the second inner end may have a sloped surface.

In various embodiments, the second outer end may have a sloped surface to be slidably placed on the second inner end.

In various embodiments, the exhaust duct may comprise aluminum, AI203, or AIN.

In various embodiments, each of the holes may be circler shaped.

In various embodiments, the hole diameter may be 1 to 30 mm.

In various embodiments, the number of the hole may be 1 to 100XX.

In various embodiments, the substrate processing apparatus may further comprise an exhaust port disposed to the bottom of the chamber wall to be fluidly coupled to the holes.

In various embodiments, the exhaust port may be fluidly coupled to a vacuum pump through a foreline.

In various embodiments, the gas supply unit may comprise a showerhead provided with a plurality of holes for supplying gas to the substrate.

In various embodiments, a substrate processing apparatus may comprise a reaction chamber provided with a chamber wall; a susceptor disposed within the reaction chamber to support a substrate; a gas supply unit to supply a gas to the substrate; and an exhaust duct disposed within the reaction chamber, comprising: an inner ring, the inner ring comprising a first inner end and a second inner end, and wherein the first inner end may comprise a plurality of first protrusions and a second protrusion; wherein the plurality of first protrusions may be configured to contact a bottom of the chamber wall; and an outer ring provided with a plurality of holes, the outer ring comprising a first outer end and a second outer end; wherein the first outer end may be configured to contact a side of the chamber wall and the second outer end is configured to be engaged with the second inner end.

In various embodiments, the second inner end may have a sloped surface.

In various embodiments, the second outer end may have a sloped surface to be slidably placed on the second inner end.

In various embodiments, a gap may be provided between the second protrusion and a bottom of the chamber wall

In various embodiments, an exhaust port may be disposed to the bottom of the chamber wall to be fluidly coupled to the holes and the gap through a space between the first protrusions.

In various embodiments, the first protrusions may be provided every 120 degrees.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic plan view of a semiconductor processing apparatus with dual chamber modules usable in an embodiment of the present invention.

FIG. 2 is a schematic cross-sectional view of a prior reaction chamber.

FIG. 3A is a schematic cross-sectional view of a prior exhaust duct.

FIG. 3B is a schematic cross-sectional view of an exhaust duct in an embodiment of the present invention.

FIG. 4 is a schematic cross-sectional view of an exhaust duct in another embodiment of the present invention.

FIG. 5 is a schematic bottom view of the exhaust duct of FIG. 4.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied.

As used herein, the term “substrate” may refer to any underlying material or materials that may be used, or upon which, a device, a circuit, or a film may be formed, which is typically semiconductor wafer.

As used herein, the term “film” and “thin film” may refer to any continuous or noncontinuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

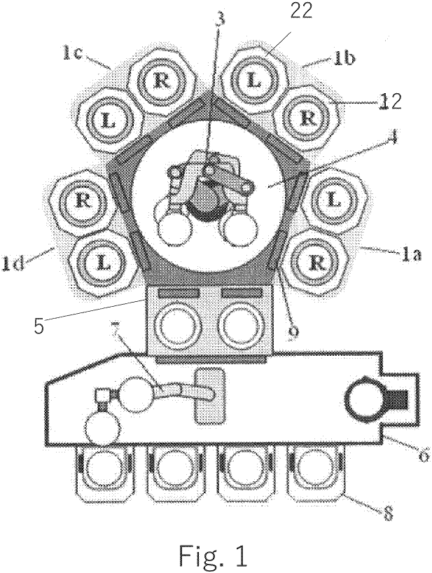

FIG. 1 is a schematic plan view of a substrate processing apparatus with dual chamber modules in an embodiment of the present invention. The substrate processing apparatus may comprise: (i) four process modules 1a-1d, each having two reaction chambers 12, 22 arranged side by side with their fronts aligned in a line; (ii) a substrate handling chamber 4 including two back end robots 3 (substrate handling robots); and (iii) a load lock chamber 5 for loading or unloading two substrates simultaneously, the load lock chamber 5 being attached to the one additional side of the substrate handling chamber 4, wherein each back end robot 3 is accessible to the load lock chamber 5. Each of the back end robots 3 have at least two end-effectors accessible to the two reaction chambers of each unit simultaneously, the substrate handling chamber 4 having a polygonal shape having four sides corresponding to and being attached to the four process modules 1a-1d, respectively, and one additional side for the load lock chamber 5, all the sides being disposed on the same plane. The interior of each reaction chamber 12, 22 and the interior of the load lock chamber 5 may be isolated from the interior of the substrate handling chamber 4 by a gate valve 9.

In some embodiments, a controller (not shown) may store software programmed to execute sequences of substrate transfer, for example. The controller may also: check the status of each process chamber; position substrates in each process chamber using sensing systems, control a gas box, and an electric box for each module; control a front end robot 7 in an equipment front end module 6 based on a distribution status of substrates stored in FOUP 8 and the load lock chamber 5; control the back end robots 3; and the control gate valves 9 and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of reaction chambers and process modules greater than one (e.g., 2, 3, 4, 5, 6, or 7). In FIG. 1, the apparatus has eight reaction chambers, but it may have ten or more. In some embodiments, the reactors of the modules may be any suitable reactors for processing or treating wafers, including CVD reactors (such as plasma-enhanced CVD reactors and thermal CVD reactors) or ALD reactors (such as plasma-enhanced ALD reactors and thermal ALD reactors). Typically, the reaction chambers may be plasma reactors for depositing a thin film or layer on a wafer. In some embodiments, all the modules may be of the same type having identical capabilities for treating wafers so that the unloading/loading can sequentially and regularly be timed, thereby increasing productivity or throughput. In some embodiments, the modules may have different capabilities (e.g., different treatments) but their handling times may be substantially identical.

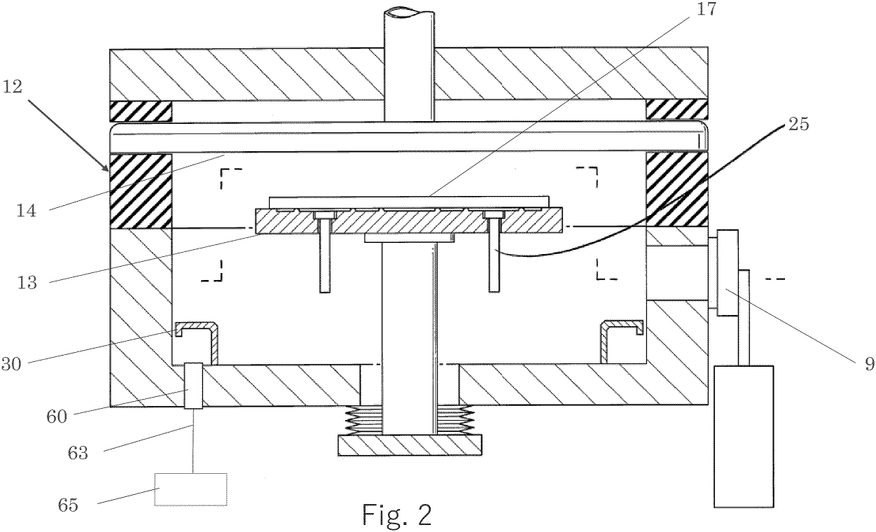

FIG. 2 is a schematic cross-sectional view of a prior reaction chamber. In the reaction chamber 12, a shower plate 14 and a susceptor 13 may be provided. The susceptor 13 may support a substrate 17 and be heated by an incorporated heater or an external heater, thereby controlling a temperature of the substrate.

The shower plates 14 may be constructed and arranged to face the susceptors 13. The shower plates 14 may be provided with a plurality of holes such a process gas is supplied to the substrate placed on the susceptor 13, thereby causing the deposition of a thin film onto the substrate 17.

A remote plasma unit (RPU) (not shown) may be disposed above the reaction chamber 12. A cleaning gas may be supplied to the RPU from a cleaning gas source (not shown), thereby turning into gas radicals, gas ions, or both (reactive gases). The reaction chamber 12 includes a chamber wall. An exhaust duct 30 is disposed within the reaction chamber (12).

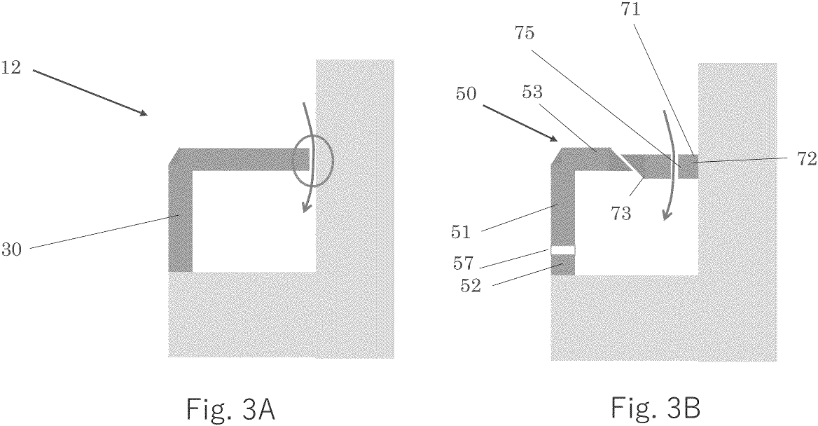

FIG. 3A is a schematic cross-sectional view of a prior exhaust duct. The exhaust duct 30 is ring-shaped. Due to a misalignment of the exhaust duct 30, evacuation of the gases around a substrate is sometimes not symmetrical since a gap between the exhaust duct and a sidewall of the chamber wall is not uniform

FIG. 3B is a schematic cross-sectional view of an exhaust duct 50 in an embodiment of the present invention. In this embodiment, the exhaust duct 50 may comprise an inner ring 51 comprising a first inner end 52 and a second inner end 53. The first inner end 52 may be configured to contact a bottom of the chamber wall. The first inner end 52 may be provided with a plurality of holes 57. The first inner end may have a plurality of slits at the end and be configured to partly contact the bottom of the chamber wall. The holes 57 and the slits may work as gas exhaust ports.

The exhaust duct 50 may further comprise an outer ring 71 provided with a plurality of holes 75. The holes 75 may work as gas exhaust ports. Each of the holes 75 may be circler shaped. The hole diameter of the hole 75 may be 1 to 30 mm and the number of the hole 75 may be 1 to 100. The outer ring 71 may comprise a first outer end 72 and a second outer end 73. The first outer end 72 may be configured to contact a side of the chamber wall and the second outer end 73 may be configured to be engaged with the second inner end 53. The outer ring 75 may be divided, for example, three outer rings may be provided every 120 degrees. The inner ring 51 may have a L-shaped cross section.

The second inner end 53 may have a sloped surface. The second outer end 73 may also have a sloped surface, which may allow the outer ring 71 to be slidably placed on the inner ring 51. Therefore, an accurate alignment can be achieved while maintaining a constant exhaust by the holes 75, resulting in more uniform processing of substrates.

The substrate processing apparatus may further include an exhaust port 60 disposed to the bottom of the chamber wall to be fluidly coupled to the holes 75. The exhaust port 60 may be fluidly coupled to a vacuum pump 65 through a foreline 63. The exhaust duct 50 may comprise aluminum, AI203, or AIN.

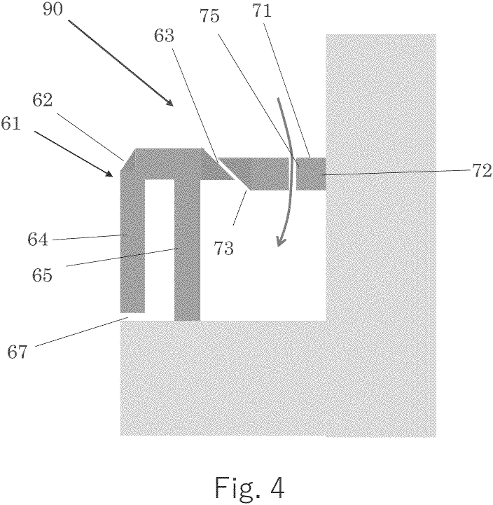

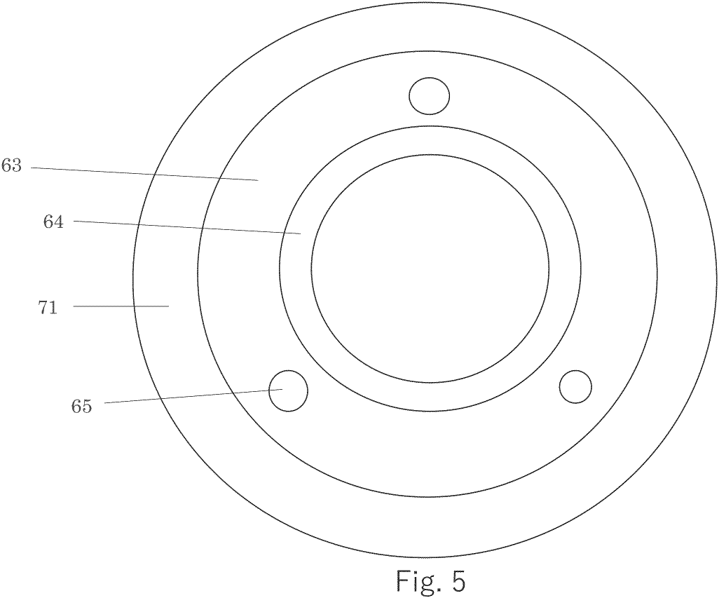

FIG. 4 is a schematic cross-sectional view of an exhaust duct 90 in another embodiment of the present invention. FIG. 5 is a schematic bottom view of the exhaust duct of FIG. 4. The exhaust duct 90 may comprise an inner ring 61, which may include a first inner end 62 and a second inner end 63. The first inner end 62 may comprise a plurality of first protrusions 65 and a second protrusion 64. The plurality of first protrusions 65 may be configured to contact a bottom of the chamber wall. The second inner end 63 may have a sloped surface, which may allow the outer ring 71 to be slidably placed on the inner ring 61. Therefore, an accurate alignment can be achieved while maintaining a constant exhaust by the holes 75, resulting in more uniform processing of substrates.

In this embodiment, a gap 67 may be provided between the second protrusion 64 and a bottom of the chamber wall. The exhaust port 60 may be fluidly coupled to the holes 75 and the gap 67 through a space between the first protrusions 65. The first protrusions 65 may be provided every 120 degrees.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a reaction chamber provided with a chamber wall;
a susceptor disposed within the reaction chamber to support a substrate;
a gas supply unit to supply a gas to the substrate; and
an exhaust duct disposed within the reaction chamber, comprising:
an inner ring comprising a first inner end and a second inner end;
wherein the first inner end is configured to contact a bottom of the chamber wall; and
an outer ring provided with a plurality of holes, the outer ring comprising a first outer end and a second outer end;
wherein the first outer end is configured to contact a side of the chamber wall and the
second outer end is configured to be engaged with the second inner end.

2. The substrate processing apparatus according to claim 1, wherein the first inner end comprises a plurality of holes.

3. The substrate processing apparatus according to claim 1, wherein the first inner end comprises a plurality of slits at the end.

4. The substrate processing apparatus according to claim 1, wherein the inner ring has a L-shaped cross section.

5. The substrate processing apparatus according to claim 4, wherein the second inner end has a sloped surface.

6. The substrate processing apparatus according to claim 5, wherein the second outer end has a sloped surface to be slidably placed on the second inner end.

7. The substrate processing apparatus according to claim 1, wherein the exhaust duct comprises aluminum, Al₂O₃, or AIN.

8. The substrate processing apparatus according to claim 1, wherein each of the holes is circler shaped.

9. The substrate processing apparatus according to claim 8, wherein the hole diameter is 1 to 30 mm.

10. The substrate processing apparatus according to claim 9, wherein the number of the hole is 1 to 100.

11. The substrate processing apparatus according to claim 1, further comprising an exhaust port disposed to the bottom of the chamber wall to be fluidly coupled to the holes.

12. The substrate processing apparatus according to claim 11, wherein the exhaust port is fluidly coupled to a vacuum pump through a foreline.

13. The substrate processing apparatus according to claim 1, wherein the gas supply unit comprise a showerhead provided with a plurality of holes for supplying gas to the substrate.

14. A substrate processing apparatus, comprising:
a reaction chamber provided with a chamber wall;
a susceptor disposed within the reaction chamber to support a substrate;
a gas supply unit to supply a gas to the substrate; and
an exhaust duct disposed within the reaction chamber, comprising:
an inner ring, the inner ring comprising a first inner end and a second inner end, and
wherein the first inner end comprises a plurality of first protrusions and a second protrusion;
wherein the plurality of first protrusions are configured to contact a bottom of the chamber wall; and
an outer ring provided with a plurality of holes, the outer ring comprising a first outer end and a second outer end;
wherein the first outer end is configured to contact a side of the chamber wall and the second outer end is configured to be engaged with the second inner end.

15. The substrate processing apparatus according to claim 14, wherein the second inner end has a sloped surface.

16. The substrate processing apparatus according to claim 15, wherein the second outer end has a sloped surface to be slidably placed on the second inner end.

17. The substrate processing apparatus according to claim 14, wherein a gap is provided between the second protrusion and a bottom of the chamber wall.

18. The substrate processing apparatus according to claim 17, further comprising an exhaust port disposed to the bottom of the chamber wall to be fluidly coupled to the holes and the gap through a space between the first protrusions.

19. The substrate processing apparatus according to claim 14, wherein the first protrusions are provided every 120 degrees.
